(19) United States
(12) Patent Application Publication
(10) Pub. No.: US 2019/0170313 A1
(43) Pub. Date: Jun. 6, 2019

(54) MODULE FOR EMITTING WHITE LIGHT WITH AN ENRICHED SPECTRUM

(71) Applicant: VALEO VISION, Bobigny Cedex (FR)

(72) Inventor: Pierre ALBOU, Bobigny Cedex (FR)

(73) Assignee: VALEO VISION, Bobigny Cedex (FR)

(21) Appl. No.: 16/314,245

(22) PCT Filed: Jun. 23, 2017
(86) PCT No.: PCT/EP2017/065602

§ 371 Date: Dec. 28, 2018

(30) Foreign Application Priority Data
Jun. 30, 2016 (FR) 1656265

(51) Int. Cl. F21S 41/153; H01L 27/15; F21S 41/143; H01L 33/06; H01L 33/32

(52) U.S. Cl. CPC F21S 41/153; H01L 27/156; F21Y 2115/10; H01L 33/06; H01L 33/32; F21S 41/143

(57) ABSTRACT

The invention relates to a semiconductor light source comprising at least a first set of light-emitting rods having submillimetric dimensions and a second set of light-emitting rods having submillimetric dimensions, the light-emitting rods of the first set being capable of emitting in a first wavelength domain and the light-emitting rods of the second set being capable of emitting in a second wavelength domain, said second domain being different from the first domain, wherein the first set of rods and the second set of rods are intermingled.

The invention relates to the field of lighting and/or signalling, notably for motor vehicles.

It may be applied, notably, to the headlights, the bodywork or the passenger compartment of a motor vehicle.

The light sources used for lighting and signalling in motor vehicles increasingly take the form of light-emitting diodes, notably because of their advantages in terms of overall dimensions and endurance, compared with conventional light sources. The use of light-emitting diodes in lighting and/or signalling modules has also enabled participants in the market, such as motor vehicle manufacturers and designers of lighting and/or signalling devices, to add a creative touch to the design of these devices, notably for the use of an increasing number of these light-emitting diodes to provide optical effects.

Such diodes usually have a narrow emission spectrum in the form of a peak centred on a given wavelength.

However, it may be desirable, notably in lighting applications, for main beam or low beam lighting for example, to provide white light illumination, requiring a richer spectrum than a simple peak centred on a given wavelength.

For this purpose, a first known solution consists in using a 2D light-emitting diode with ultraviolet emission coupled to a phosphorescent luminophore having an emission spectrum covering the whole domain visible to the human eye. Ultraviolet emission is very high in energy, but has the drawback of causing a degradation of the luminophore and/or the optical hardware of the lighting or signalling device. This limits the life of the lighting/signalling device. Furthermore, the use of a phosphorescent luminophore results in low efficiency in terms of conversion.

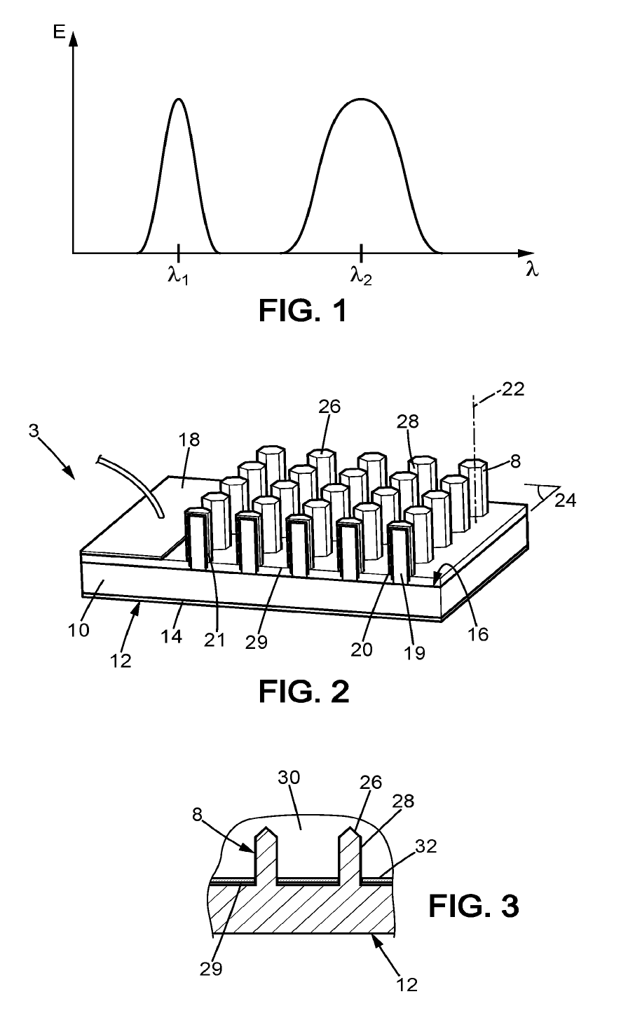

A second solution consists in using a white diode composed of a light-emitting diode emitting a spectrum having a peak in the blue-violet region, that is to say centred on 450 nm, coupled to a fluorescent luminophore having a wider emission spectrum in the yellow-green region, that is to say centred on 570 nm. The spectrum of such a light source is illustrated with reference to FIG. 1, in which the peak in the blue region is centred on the wavelength λ₁ and the wider spectrum in the yellow-green region is centred on the wavelength λ₂.

Although such lighting may appear white when viewed directly, it is very poor on objects having a spectral reflectance located in the troughs of the emission spectrum of the light source. For example, blue objects such as advisory signs according to French law, or red objects such as prohibition and danger signs according to French law, appear black. Thus the colour rendering is poor.

The present invention is intended to improve the situation.

One aspect of the invention relates to a semiconductor light source comprising at least a first set of light-emitting rods having submillimetric dimensions and a second set of light-emitting rods having submillimetric dimensions, the light-emitting rods of the first set being capable of emitting in a first wavelength domain and the light-emitting rods of the second set being capable of emitting in a second wavelength domain, the second domain being different from the first domain. The first set of rods and the second set of rods are intermingled.

By comparison with the diagram of FIG. 1, the spectrum of the light-emitting module is far richer, thus providing white light illumination with better colour rendering.

Additionally, by using light-emitting rods of different kinds it is possible to achieve such an enrichment of the light spectrum while allowing fine interleaving.

According to an embodiment, the light source may further comprise a matrix comprising at least a first luminescent material, at least some of the light-emitting rods being embedded in the matrix and the first luminescent material being capable of absorbing light in an absorption spectrum comprising at least one wavelength from the first domain or the second domain, and being capable of emitting in a third wavelength domain, the third domain being different from the first domain and the second domain.

This embodiment also enables the emission spectrum of the light source to be enriched.

In a variant, the first luminescent material may be a fluorescent material.

This variant makes it possible to avoid degrading the luminescent material and/or the optical hardware of the light source, thus improving its service life.

According to an embodiment, the rods of the first set and the rods of the second set may be intermingled by alternation of groups of rods of the first set and groups of rods of the second set.

Thus the interleaving of the source is fine and enables a coherent light source to be provided.

Additionally, the light-emitting rods of each group may be distributed in a single geometric pattern.

Such an embodiment facilitates the production of the light source and the electrical power supply of the light-emitting rods.

In a variant, the light-emitting rods of the first set and the light-emitting rods of the second set may be intermingled in a random way.

The coherence of the light source is thus improved.

In an embodiment of the invention, two consecutive rods in a given direction of the same set, separated by at least one light-emitting rod of the other set, are separated by a distance of less than 100 micrometres.

For example, the groups of light-emitting rods of the first and the second set alternate with an interval of less than 100 micrometres.

Thus the human eye cannot distinguish the alternation of groups, and the coherence of the light source is improved.

According to an embodiment of the invention, the first wavelength domain may comprise a wavelength of 445 nanometres, and the second wavelength domain may comprise a wavelength of 467 nm.

In a variant, the first wavelength domain may comprise a wavelength of 445 nm, and the second wavelength domain may comprise a wavelength greater than or equal to 600 nm.

Additionally, the first luminescent material comprises a cerium-YAG luminophore having an emission domain comprising at least one wavelength in the range from 573 nm to 584 nm.

Thus the spectrum of the light emitted by the light source is enriched.

Additionally, or as a variant, the light source may further comprise a third set of light-emitting rods capable of emitting in a third wavelength domain, the third wavelength domain possibly comprising a wavelength of 467 nm.

Thus the spectrum of the light emitted by the light source is enriched.

According to another variant, the first wavelength domain may comprise a wavelength of 445 nanometres, and the second wavelength domain may comprise a wavelength in the range from 573 to 584 nm, the matrix comprising a second luminescent material being capable of absorbing light in an absorption spectrum comprising at least one wavelength of the first domain or the second domain, and capable of emitting light in a fourth wavelength domain comprising a wavelength of 465 nm.

Thus the spectrum of the light emitted by the light source is enriched. Examples of luminescent materials are described below.

A second aspect of the invention relates to a light-emitting module for a motor vehicle comprising a light source according to the first aspect of the invention.

According to an embodiment, the module further comprises a first voltage generator capable of supplying the first set of light-emitting rods and a second voltage generator capable of supplying the second set of light-emitting rods.

Thus sets of rods having different nominal voltages may be supplied.

In a variant, the module may further comprise a voltage generator, j groups of the first set may be placed in series and supplied in parallel with k groups of the second set, j and k being defined in such a way that the product of j and the nominal voltage of a group of the first set is substantially equal to the product of k and the nominal voltage of a group of the second set.

Thus sets of rods having different nominal voltages may be supplied while using a single voltage generator. The cost and overall dimensions of the light-emitting module are thus reduced.

According to an embodiment, the module further comprises a shaping optic capable of receiving the light emerging from the light source and shaping a light beam.

A shaping optic deflects at least one of the light rays of the light emitted by the light source. “Deflected” is taken to mean that the direction of entry of the light ray into the shaping optic is different from the direction of exit of the light ray from the shaping optic. The shaping optic comprises at least one optical element such as one or more lenses, one or more reflectors, one or more light guides, or a combination of these possibilities.

A third aspect of the invention relates to a light-emitting device, notably for lighting and/or signalling for a motor vehicle, comprising a lighting module according to the second aspect of the invention in such a way as to form at least a part of the light beam.

According to an embodiment, the device may further comprise a casing and a sealing lens interacting with one another to delimit an interior cavity comprising the light-emitting module.

A fourth aspect of the invention relates to a method of manufacturing a light-emitting module, notably for a motor vehicle, comprising a semiconductor light source, the method comprising the following steps:
growing, on a substrate, a first set of light-emitting rods having submillimetric dimensions, capable of emitting in a first wavelength domain;
growing, on a substrate, a second set of light-emitting rods having submillimetric dimensions, capable of emitting in a second wavelength domain, the second domain being different from the first domain.
   The first set of rods and the second set of rods are intermingled.

Other characteristics and advantages of the invention will be apparent from a perusal of the following detailed description and the attached drawings, in which:

FIG. 1 shows an emission diagram of a light-emitting module according to the prior art;

FIGS. 2 and 3 show the structure of a plurality of light-emitting rods of a light-emitting module according to an embodiment of the invention;

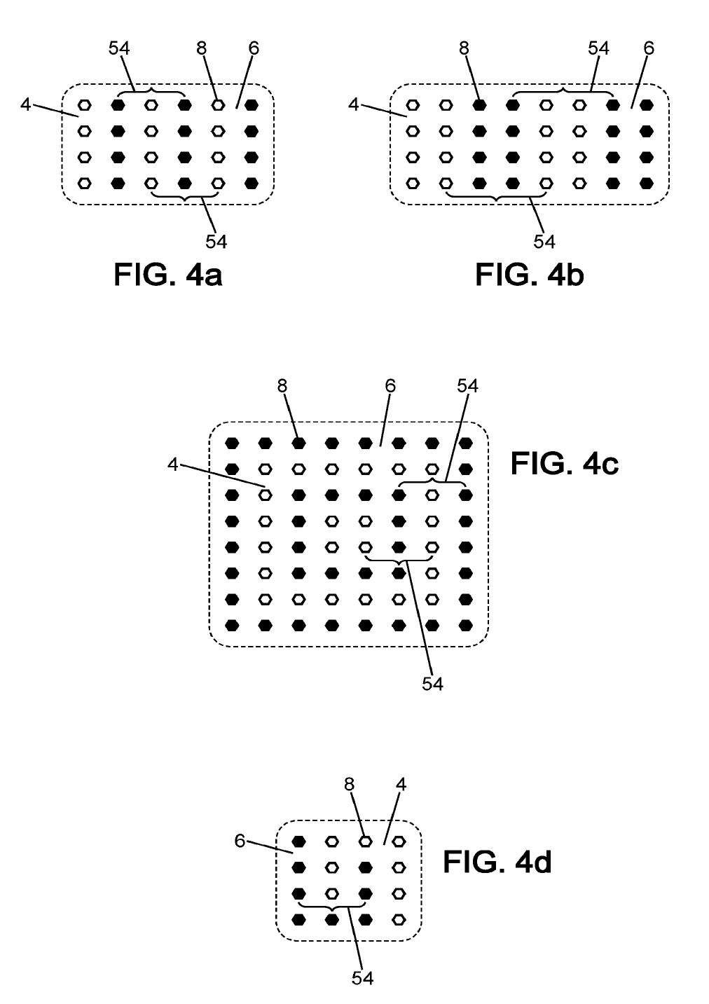

FIGS. 4a to 4d show intermingled arrangements of two sets of light-emitting rods according to embodiments of the invention;

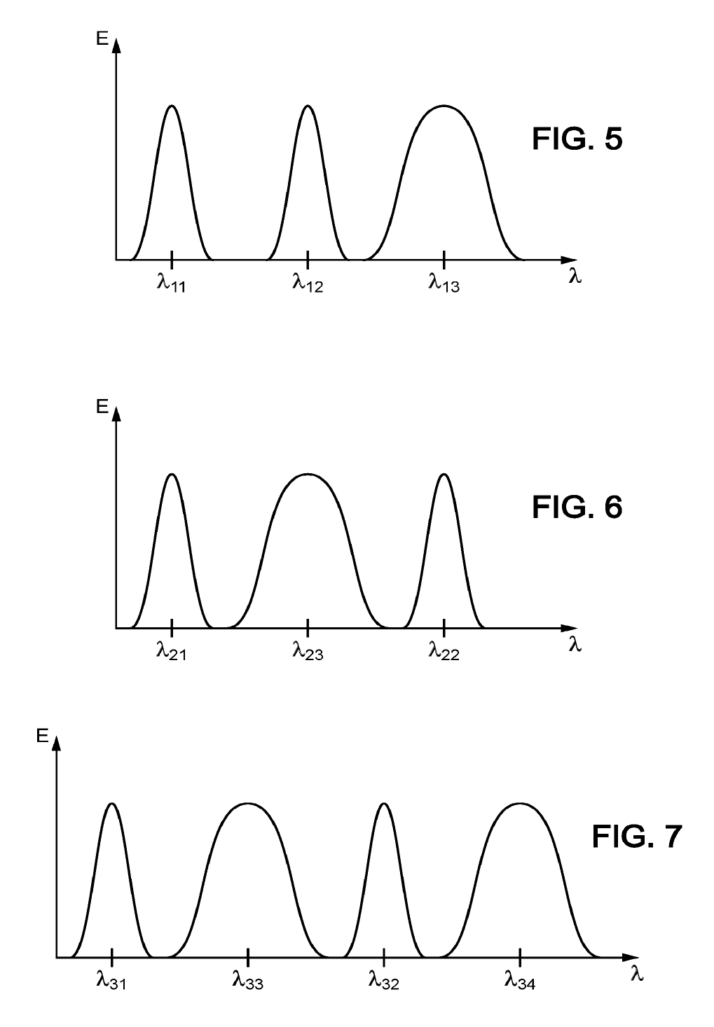

FIG. 5 shows an emission diagram of a light-emitting module according to a first embodiment of the invention;

FIG. 6 shows an emission diagram of a light-emitting module according to a second embodiment of the invention;

FIG. 7 shows an emission diagram of a light-emitting module according to a third embodiment of the invention;

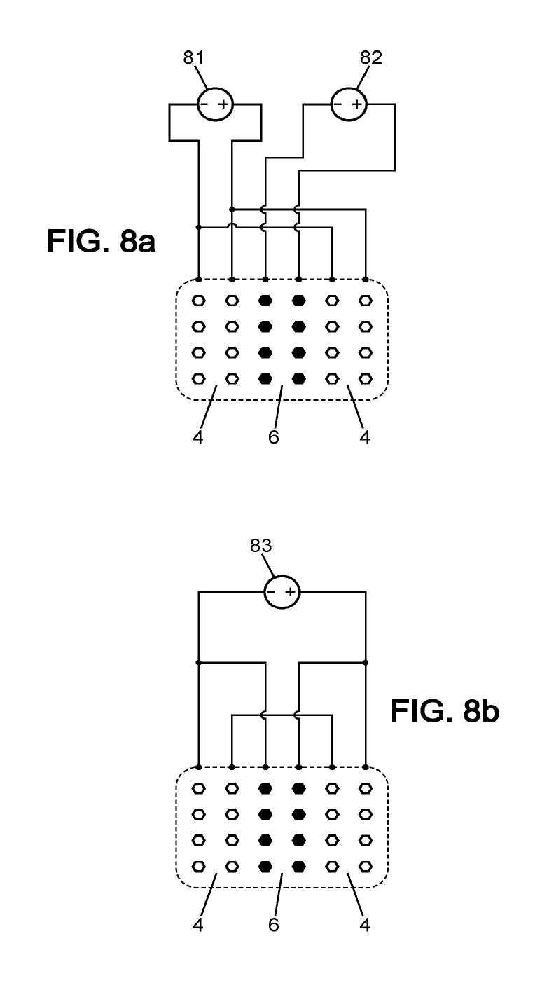

FIGS. 8a and 8b show power supply means of a light source according to two embodiments of the invention.

FIGS. 2 and 3 show the structure of a plurality of light-emitting rods, having submillimetric dimensions, of a light source according to the invention.

The light source according to the invention may be integrated into a light-emitting module, which may also include a shaping optic receiving light emerging from the light source so as to shape an outgoing light beam. Such a light-emitting module may be integrated into a light-emitting device, notably for lighting and/or signalling in a motor vehicle. Such a light-emitting device may further comprise a casing and a sealing lens interacting with one another to delimit an interior cavity comprising the light-emitting module.

The device is, for example, a lighting device, in which case it forms a vehicle headlight, or front lamp. In this case it is configured to implement one or more lighting functions, which may include, notably, a low beam function also called a “dipped” function, a high beam function also called a “main beam” function, and a fog beam function.

Alternatively, the device is a signalling device designed to be positioned at the front or rear of the vehicle. When it is designed to be positioned at the front, it is, for example, configured to implement one or more signalling functions which may include a direction indicator function, a daytime running light function (abbreviated to DRL), and a front signature lighting function. When it is designed to be positioned at the rear, it is, for example, configured to implement one or more functions which may include a reversing light function, a fog light function, a brake light function, a direction indicator function, and a rear signature lighting function.

Alternatively, the device is provided for lighting the passenger compartment of a vehicle, in which case it is designed to emit light mainly in the vehicle's passenger compartment.

With reference to FIGS. 2 and 3, the light source comprises a plurality of light-emitting rods 8, which originate from at least one substrate 10. Each light-emitting rod 8 extends perpendicularly, or substantially perpendicularly, in projection from the substrate 10, and may be made of silicon, silicon carbide, or other materials that may be used without departure from the context of the invention.

As described below, the light-emitting module comprises at least a first set of light-emitting rods having submillimetric dimensions and a second set of light-emitting rods having submillimetric dimensions, the light-emitting rods of the first set being capable of emitting in a first wavelength domain and the light-emitting rods of the second set being capable of emitting in a second wavelength domain, the second domain being different from the first domain. For this purpose, the rods of the first set and of the second set may be made of different compounds, such as, for example, a compound based on gallium nitride (GaN), a compound based on aluminium nitride and gallium nitride (AlGaN), or a compound based on aluminium, indium and gallium (AlInGaN).

The substrate 10 has a lower face (12), on which a first electrode 14 is applied, and an upper face 16, from which the light-emitting rods 8 extend in a projecting manner and on which a second electrode 18 is applied. Different layers of materials are superimposed on the upper face 16, notably after the growth of the light-emitting rods from the substrate 10, produced by an upward procedure in this case. These different layers may include at least one layer of electrically conductive material for the electrical power supply to the rods. This layer is etched so as to connect certain rods with one another, so that these light-emitting rods may then be made to light up simultaneously by a control module, not shown here. As discussed below, the rods of the first set and those of the second set may be powered separately or jointly.

The light-emitting rods 8 extend from the substrate, and, as may be seen in FIG. 2, each of them includes a core 19, comprising one of the components GaN, AlGaN, AlInGaN or other component mentioned above, around which are arranged quantum wells formed by a radial superimposition of layers of different materials, for example gallium nitride and gallium-indium nitride, and a shell 21, possibly made of the same material as the core 19, surrounding the quantum wells.

Each light-emitting rod 8 extends along a longitudinal axis 22 defining its height, the base of each rod being arranged in a plane 24 of the upper face 16 of the substrate 10.

The light-emitting rods 8 of the same light-emitting module may advantageously have the same shape. Each of them is delimited by an end face 26 and by a circumferential wall 28 extending along the longitudinal axis. When the light-emitting rods 8 are doped and biased, the resulting light at the output of the light-emitting module is emitted essentially from the circumferential wall 28, although it should be understood that the light rays may also pass out from the end face 26. Consequently, each light-emitting rod 8 acts as a single light-emitting diode, and the lighting efficiency of this source is improved, on the one hand, by the density of the light-emitting rods 8 present, and, on the other hand, by the size of the illuminating surface which is defined by the circumferential wall and which therefore extends over the whole periphery and the whole length of the rod.

The circumferential wall 28 of a light-emitting rod 8, corresponding to the shell 21, may be covered by a layer of transparent conductive oxide (TCO) 29 which forms the anode of each rod, being complementary to the cathode formed by the substrate 10. This circumferential wall 28 extends along the longitudinal axis 22 from the substrate 10 to the end face 26, the distance from the end face 26 to the upper face 16 of the substrate 10, from which the light-emitting rods 8 originate, defining the height of each rod. By way of example, provision may be made for the height of a light-emitting rod 8 to be between 1 and 10 micrometres, and for the largest transverse dimension of the end face, perpendicularly to the longitudinal axis 22 of the rod concerned, to be less than 2 micrometres. It is also possible to define the surface of a rod, in a section plane perpendicular to this longitudinal axis 22, within a specified range of values, and notably between 1.96 and 4 square micrometres.

Evidently, during the formation of the light-emitting rods 8 of the first set and of the second set, the height may be modified from one set to the other, so as to increase the luminance of one or other of the sets when the average height of its constituent rods is increased.

The shape of the light-emitting rods 8 may also vary from one set to the other, notably as regards the cross section of the rods and the shape of the end face 26. The light-emitting rods 8 may have a generally cylindrical shape, and they may notably, as shown in FIG. 2, have a shape with a polygonal, and more particularly hexagonal, cross section. Evidently, it is important that the light may be emitted through the circumferential wall, regardless of whether the wall has a polygonal or circular shape.

Additionally, the end face 26 may have a substantially flat shape, perpendicular to the circumferential wall, so that it extends substantially parallel to the upper face 16 of the substrate 10, as shown in FIG. 2; alternatively, it may have a domed or centrally pointed shape, so as to multiply the directions of emission of the light leaving this end face, as shown in FIG. 3.

The light-emitting rods 8 may be arranged in a two-dimensional matrix. This arrangement may be such that the rods are arranged quincuncially. As a general rule, the rods are arranged at regular intervals on the substrate 10, and the separation distance two immediately adjacent light-emitting rods, in each dimension of the matrix, is equal to not less than 2 micrometres, so that the light emitted by the circumferential wall 28 of each light-emitting rod 8 can pass out of the matrix 30 of light-emitting rods. Provision may also be made for these separating distances, measured between two longitudinal axes 22 of adjacent rods, to be not more than 100 micrometres.

The light-emitting module may also include, as shown in FIG. 3, a layer or matrix 30 of a polymer material in which the light-emitting rods 8 are at least partially embedded. The layer 30 may thus extend over the whole extension of the substrate, or only around a specified group of light-emitting rods 8. The polymer material, which may, notably, be silicone-based, creates a protective layer enabling the light-emitting rods 8 to be protected without interfering with the diffusion of the light rays. It is also possible to integrate into this matrix 30 of polymer material wavelength conversion means, for example a luminescent material, also referred to below as a luminophore, capable of absorbing at least some of the rays emitted by at least one of the light-emitting rods 8 and of converting at least some of the absorbed excitation light into an emission light having a different wavelength from that of the excitation light. More generally, a luminescent material absorbs light in a first wavelength domain and emits light in a second wavelength domain which is distinct from the first domain, being wider and centred on a different wavelength. Provision may be made for the luminescent material to be embedded in the matrix 30, or for it to be arranged on the surface of the layer of this matrix 30.

Among luminescent materials, we may distinguish, notably, phosphorescent materials of luminescent materials.

Fluorescent materials absorb light in a restricted absorption domain and re-emit in an emission domain that is wider and offset relative to the absorption domain, while providing good conversion efficiency.

As for phosphorescent materials, these absorb light regardless of its wavelength, and re-emit in a wider emission domain than that of fluorescent materials. However, their efficiency is markedly lower than that of fluorescent materials.

The light source may also include a coating 32 of light-reflecting material which is arranged between the light-emitting rods 8, for deflecting the rays that were initially orientated towards the substrate towards the end face 26 of the light-emitting rods 8. In other words, the upper face 16 of the substrate 10 may include a reflective means which reflects the light rays that were initially orientated towards the upper face 16 towards the exit face of the light-emitting module. It is thus possible to recover light rays that would have been lost otherwise. This coating 32 is arranged between the light-emitting rods 8 on the layer of transparent conductive oxide 29.

According to the invention, the light source has a first set and a second set of light-emitting rods emitting in different wavelength domains, the first and second sets being intermingled with one another.

“intermingled sets” is taken to mean sets which are mixed with one another, and which, depending on the configurations of the light-emitting module, may be interleaved or interwoven with one another. An intermingling covers any arrangement of rods in which, for at least a first segment connecting two rods of the first set, the first segment passes through at least a part of the second set, and in which, for at least a second segment connecting two rods of the second set, the second segment passes through at least a part of the first set.

FIGS. 4a to 4d show embodiments of the intermingling of the first and second sets of light-emitting rods 8.

In FIG. 2 and in the embodiments of FIGS. 4a to 4d, the light-emitting module has a rectangular shape overall, but evidently it may have other overall shapes, and notably a parallelogram shape, without departure from the scope of the invention.

A number of examples of embodiment of the intermingling of the first and second sets of light-emitting rods 8 will now be described.

The first set, bearing the reference 4 in FIGS. 4a to 4d, and the second set, bearing the reference 6 in FIGS. 4a to 4d, each comprise a plurality of light-emitting rods 8 having submillimetric dimensions. In the examples of FIGS. 4a to 4c, each of the first and second set comprises a plurality of collections, referred to hereafter as groups, of light-emitting rods 8. For example, two groups of rods of the first set are separated by one group of rods of the second set.

Provision may be made for the separation distance between a rod of the first set 4 and a directly adjacent rod belonging to the second set 6 to be substantially equal to the separation distance between two light-emitting rods of the same set, this separation distance, measured between two longitudinal axes of light-emitting rods, being equal to not less than 2 micrometres, so that the light emitted by the circumferential wall 28 of each rod 8 can pass out of the matrix of light-emitting rods.

As shown in FIGS. 4a to 4d, the sets 4 and 6 are mixed in an intrusive manner; that is to say, each set is divided into groups of rods, in FIGS. 4a to 4c, and the groups of rods of the first set and the groups of rods of the second set alternate in a geometrical pattern. Alternatively, the alternation between the groups may be random.

The patterns in FIGS. 4a to 4d may be considered as elementary patterns that may be repeated and/or combined.

FIGS. 4a and 4b show regular arrangements in which the groups of rods are strips, one rod wide in FIG. 4a, and two rods wide in FIG. 4b. In FIG. 4a, each group of rods of the first set 4 or of the second set 6 comprises four light-emitting rods, while in FIG. 4b each group comprises eight light-emitting rods. Provision may be made for the groups of light-emitting rods of the first set 4 and the groups of light-emitting rods of the second set 6 to comprise different numbers of light-emitting rods 8.

In FIG. 4c, the groups of sets 4 and 6 are not of the same size, and each has a different number of light-emitting rods 8. The groups are arranged around one another so that a group of the first set 4 is surrounded by two groups of the second set 6, and vice versa. In the case shown in FIG. 4c, the successive layers take the form of squares arranged around one another, but provision could be made for the light-emitting rods to be arranged in substantially circular and concentric groups.

As shown in FIG. 4d, the intermingling of the sets 4 and 6 may be provided by intrusive shapes of light-emitting rods of one set inside an area occupied by the other set.

As shown in FIGS. 4a to 4d, the distance separating two consecutive rods, belonging to the same set, in a given direction may be considered. Such a distance is at its maximum when the two rods in question are separated by light-emitting rods of the other set. This maximum distance between two consecutive rods of the same set bears the reference 54 in FIGS. 4a to 4d.

As explained above, the light-emitting rods of the first set 4 and the light-emitting rods of the second set 6 are capable of emitting light in different wavelength domains. To ensure good synthesis by the eye, and to ensure, notably, that the eye cannot distinguish the different groups, provision may advantageously be made for the intermingling of the first and second sets to be such that the distances 54 are always less than 100 micrometres, corresponding to the optical resolution of the human eye.

The invention also proposes a method of manufacturing the light source described above. For this purpose, the method comprises a step of growing on a substrate a first set of light-emitting rods with submillimetric dimensions, capable of emitting in a first wavelength domain, and a step of growing, on the same substrate, a second set of light-emitting rods with submillimetric dimensions, capable of emitting in a second wavelength domain, the first set and the second set being intermingled, as shown in FIGS. 4a to 4d for example. The first and second wavelength domains are different.

Such a growth may be carried out by a known method of epitaxy, not described below. Additionally, in order to provide the intermingling, the step of growing the first set of light-emitting rods may be executed with the aid of a mask, the mask covering an area intended for the subsequent growth of the light-emitting rods of the second set.

According to a first embodiment, the light-emitting rods 8 of the first set 4 are formed from gallium nitride and are capable of emitting in a first wavelength domain comprising a wavelength of 445 nanometres, abbreviated to “nm” hereafter (for example, the domain is centred on 445 nm), and the light-emitting rods of the second set 6 are formed from doped gallium nitride and are capable of emitting in a second wavelength domain comprising a wavelength of 467 nm (for example, the domain is centred on 467 nm).

Optionally, according to this first embodiment, the matrix 30 may also comprise a luminophore, of the cerium-YAG type for example, which absorbs light in the ultraviolet and blue regions, therefore absorbing the light from the two sets of rods, and emits in the yellow region; that is to say, the emission domain comprises at least one wavelength in the range from 573 nm to 584 nm.

FIG. 5 shows an emission diagram of the light energy of a light source according to the first embodiment of the invention, as a function of wavelength.

As indicated above, the first set 4 of light-emitting rods 8 is capable of emitting in a wavelength domain comprising at least λ₁₁=445 nm, the second set 6 of light-emitting rods 8 is capable of emitting in a wavelength domain comprising at least λ₁₂=467 nm, and the luminescent material is capable of emitting in a wavelength domain centred on λ₁₃, λ₁₃ being in the range from 573 to 584 nm.

By comparison with the diagram of FIG. 1, the spectrum of the light-emitting module is far richer, notably in the blue regions, thus providing white light illumination with better colour rendering.

Additionally, by using light-emitting rods of different kinds it is possible to achieve such an enrichment of the light spectrum while allowing fine intermingling which is not perceptible to the eye.

According to a second embodiment, the light-emitting rods of the first set 4 are formed from gallium nitride and are capable of emitting in a first wavelength domain comprising a wavelength of 445 nm. For example, the first domain is centred on 445 nm. Additionally, the light-emitting rods of the second set 6 are formed from aluminium indium gallium phosphide (AlGaInP) and are capable of emitting in a second wavelength domain comprising a wavelength of 600 nm or above. For example, the second domain is centred on a wavelength of 600 nm or above.

Optionally, according to this first embodiment, the matrix 30 may also comprise a luminophore, of the cerium-YAG type for example, which absorbs light in the ultraviolet and blue regions, therefore absorbing the light from the first set of light-emitting rods, and emits in the yellow region, the emission domain comprising at least one wavelength in the range from 573 nm to 584 nm.

FIG. 6 shows an emission diagram of the light energy of a light source according to the second embodiment of the invention, as a function of wavelength.

As indicated above, the first set 4 of light-emitting rods 8 is capable of emitting in a wavelength domain comprising at least λ₂₁=445 nm, the second set 6 of light-emitting rods 8 is capable of emitting in a wavelength domain comprising at least λ₂₂=600 nm, and the luminescent material is capable of emitting in a wavelength domain centred on λ₂₃, λ₂₃ being in the range from 573 to 584 nm.

By comparison with the diagram of FIG. 1, the spectrum of the light-emitting module is far richer, notably in the reds, thus providing white light illumination with better colour rendering.

Additionally, by using light-emitting rods of different kinds it is possible to achieve such an enrichment of the light spectrum while allowing fine intermingling which is not perceptible to the eye.

Additionally, according to the second embodiment of the invention, the light source may further comprise a third set of light-emitting rods, made of doped gallium nitride for example, capable of emitting in a third wavelength domain comprising a wavelength of 467 nm. For example, the third domain is centred on 467 nm. Thus the emission spectrum is further enriched. For this purpose, an intermingling of the three sets of light-emitting rods may be provided.

According to a third embodiment, the light-emitting rods of the first set 4 are formed from gallium nitride and are capable of emitting in a first wavelength domain comprising a wavelength of 445 nm. For example, the first domain is centred on 445 nm. Additionally, the light-emitting rods of the second set 6 are formed from aluminium indium gallium phosphide (AlGaInP) and are capable of emitting in a second wavelength domain comprising a wavelength in the range from 573 to 584 nm. For example, the second domain is centred on a wavelength of 580 nm or above.

According to this third embodiment, optionally, the matrix 30 may further comprise two luminescent materials, for example strontium sulphide doped with europium and cerium-doped YAG, one emitting in the red region, that is to say the domain of emission of wavelengths comprising a wavelength of 630 nm, and the other emitting in the yellow-green region, that is to say a domain of emission of wavelengths comprising at least a wavelength of 570 nm.

FIG. 7 shows an emission diagram of the light energy of a source according to the third embodiment of the invention, as a function of wavelength.

As indicated above, the first set 4 of light-emitting rods 8 is capable of emitting in a wavelength domain comprising at least λ₃₁=445 nm, the second set 6 of light-emitting rods 8 is capable of emitting in a wavelength domain comprising at least λ₃₂=580 nm, and the luminescent materials are, respectively, capable of emitting in a wavelength domain centred on λ₃₃ and λ₃₄, λ₃₃ being equal to 465 nm and λ₃₄ being equal to 630 nm.

For example, a luminescent material capable of emitting in a wavelength domain centred on 465 nm is Coumarin 314, which may be stabilized by adding a buffer material such as layered zinc hydroxides, which may be single or double for example, for use in solution in a polymer such as a polysiloxane. In this case, the extreme viscosity of the polymer advantageously limits the risks of leakage of the solution.

Examples of luminescent materials capable of emitting in a wavelength domain centred on 630 nm are the following compounds:

SrS:Eu²⁺, Sr₂Si₅N₈:Eu²⁺

Again, these luminescent materials may be embedded in a polysiloxane covering the light-emitting rods.

By comparison with the diagram of FIG. 1, the spectrum of the light source is far richer, thus providing white light illumination with better colour rendering.

Additionally, by using light-emitting rods of different kinds it is possible to achieve such an enrichment of the light spectrum while allowing fine intermingling which is not perceptible to the eye.

It will be evident from the embodiments described above that other combinations of light-emitting rods (two or more sets) and luminescent materials may be envisaged according to the invention.

For example, the light-emitting rods of the first set are capable of natively emitting white light. In this case, the second wavelength domain is included in the first wavelength domain, and the light-emitting rods of the second set enable the lighting to be reinforced in the second wavelength domain.

FIGS. 8a and 8b show two light-emitting modules comprising a light source according to the invention and alternative power supply means.

It should be noted that light-emitting rods of different kinds usually accept different power supply voltages. Consequently, the groups cannot all be supplied in parallel with a single voltage generator.

According to the diagram of FIG. 8a, a first voltage generator 81 is dedicated to the power supply to the groups of the first set 4 in parallel, while a second voltage generator 82 is dedicated to the power supply to the groups of the second set 6 in parallel (for the sake of simplicity, only one group of the second set 6 is shown in FIG. 8a). Thus the generators 81 and 82 may deliver different voltages.

Alternatively, a single voltage generator 83 may be provided for all the light-emitting rods of the light-emitting module.

For example, in a simplified example in which the power supply voltage of the light-emitting rods of the second group 6 is twice as high as the power supply voltage of the light-emitting rods of the first group 4, provision may be made to connect two groups of the first set in series, and to supply them in parallel with a group of the second set 6, as shown in FIG. 8b.

In the more general case in which the power supply voltage of the light-emitting rods of the first set 4 is equal to M and the power supply voltage of the light-emitting rods of the second set 6 is equal to N, ppcm(M,N)/M=j groups of the first set are connected in series, and are supplied in parallel with ppcm(M,N)/N=k groups of the second set, also connected in series. The term ppcm(M,N) denotes the lowest common multiple of the voltages M and N.

Evidently, the invention is not limited to the embodiments which are described above and which are provided solely by way of example. It encompasses various modifications, alternative forms and other variants which could be envisaged by a person skilled in the art within the scope of the present invention, and notably all combinations of the various embodiments described above.

1. Semiconductor light source comprising at least a first set of light-emitting rods having submillimetric dimensions and a second set of light-emitting rods having submillimetric dimensions, said light-emitting rods of the first set being capable of emitting in a first wavelength domain and said light-emitting rods of the second set being capable of emitting in a second wavelength domain, said second domain being different from the first domain,
wherein the first set of rods and the second set of rods are intermingled.

2. Light source according to claim 1, further comprising a matrix comprising at least a first luminescent material, at least some of the light-emitting rods being embedded in said matrix and said first luminescent material being capable of absorbing light in an absorption spectrum comprising at least one wavelength of the first domain or the second domain, and being capable of emitting in a third wavelength domain, the third domain being different from the first domain and the second domain.

3. Light source according to claim 2, wherein the first luminescent material is a fluorescent material.

4. Light source according to claim 1, wherein the light-emitting rods of the first set and the light-emitting rods of the second set are intermingled by alternation of groups of rods of the first set and groups of rods of the second set.

5. Light source according to claim 4, wherein the light-emitting rods of each group are distributed in a single geometric pattern.

6. Light source according to claim 1, wherein the light-emitting rods of the first set and the light-emitting rods of the second set are intermingled in a random manner.

7. Light source according to claim 4, wherein two consecutive rods in a given direction of the same set, separated by at least one light-emitting rod of the other set, are separated by a distance of less than 100 micrometres.

8. Light source according to claim 7, wherein the groups of light-emitting rods of the first set and the second set alternate with an interval of less than 100 micrometres.

9. Light source according to claim 1, wherein the first wavelength domain comprises a wavelength of 445 nanometres, and wherein the second wavelength domain comprises a wavelength of 467 nm.

10. Light source according to claim 2, wherein the first wavelength domain comprises a wavelength of 445 nm, and wherein the second wavelength domain comprises a wavelength of 600 nm or more.

11. Light source according to claim 10, wherein the first luminescent material comprises a cerium-YAG luminophore having an emission domain comprising at least one wavelength in the range from 573 nm to 584 nm.

12. Light source according to claim 11, further comprising a third set of light-emitting rods capable of emitting in a third wavelength domain, the third wavelength domain comprising a wavelength of 467 nm.

13. Light source according to claim 2, wherein the first wavelength domain comprises a wavelength of 445 nanometres, and wherein the second wavelength domain comprises a wavelength in the range from 573 to 584 nm;
wherein the matrix further comprises a second luminescent material being capable of absorbing light in an absorption spectrum comprising at least one wavelength of the first domain or the second domain, and capable of emitting light in a fourth wavelength domain comprising a wavelength of 465 nm.

14. Light-emitting module for a motor vehicle, comprising a light source according to claim 1.

15. Light-emitting module according to claim 14, further comprising a first voltage generator capable of supplying the first set of light-emitting rods and a second voltage generator capable of supplying the second set of light-emitting rods.

16. Light-emitting module according to claim 14, comprising a light source according to one of claims 5 and 6, and further comprising a voltage generator, wherein j groups of the first set are placed in series and supplied in parallel with k groups of the second set, j and k being defined in such a way that the product of j and the nominal voltage of a group of the first set is substantially equal to the product of k and the nominal voltage of a group of the second set.

17. Light-emitting module according to claim 15, further comprising a shaping optic capable of receiving the light emerging from the light source and shaping a light beam.

18. Light-emitting device, comprising at least a lighting module according to claim 14 in such a way as to form at least a part of a light beam.

19. Light-emitting device according to claim 18, further comprising a casing and a sealing lens interacting with one another to delimit an interior cavity comprising the light-emitting module.

20. Method of manufacturing a semiconductor light source, said method comprising the following steps:
growing, on a substrate, a first set of light-emitting rods having submillimetric dimensions, capable of emitting in a first wavelength domain;
growing, on said substrate, a second set of light-emitting rods having submillimetric dimensions, capable of emitting in a second wavelength domain, said second domain being different from the first domain,
wherein the first set of rods and the second set of rods are intermingled.
